(19) United States
(12) Patent Application Publication
(10) Pub. No.: US 2020/0042245 A1
(43) Pub. Date: Feb. 6, 2020

(54) MEMORY SYSTEM, MEMORY CONTROLLER, AND OPERATING METHOD THEREOF

(71) Applicant: SK hynix Inc., Gyeonggi-do (KR)

(72) Inventors: Hyun Woo LEE, Gyeonggi-do (KR); Young Gyun KIM, Seoul (KR)

(21) Appl. No.: 16/299,272

(22) Filed: Mar. 12, 2019

(30) Foreign Application Priority Data
Jul. 31, 2018 (KR) 10-2018-0089615

(51) Int. Cl. G06F 3/06; H03K 19/21; G11C 16/04; G11C 16/26; G06F 11/10; G11C 29/52

(52) U.S. Cl. CPC G06F 3/0659; H03K 19/21; G11C 16/0483; G11C 16/26; G11C 11/5671; G11C 29/52; G06F 3/0619; G06F 3/0679; G06F 11/1068

(57) ABSTRACT

A memory system includes a memory device and a memory controller. The memory device includes a plurality of memory cells. The memory controller controls the memory device to perform a plurality of read operations on memory cells included in a selected physical page among the plurality of memory cells. The memory controller calculates an inverted bit number representing different bit values, based on a plurality of read data received from the memory device. The memory controller performs a read reclaim operation on the selected physical page, based on the inverted bit number.

### CROSS-REFERENCE TO RELATED APPLICATION

The present application claims priority under 35 U.S.C. § 119(a) to Korean patent application number 10-2018-0089615, filed on Jul. 31, 2018, which is incorporated herein by reference in its entirety.

### BACKGROUND

### Field of Invention

The present disclosure generally relates to an electronic device, and more particularly, to a memory system, a memory controller, and an operating method thereof.

### Description of Related Art

A memory system may include a storage device and a memory controller.

The storage device may include a plurality of memory devices, and the memory devices may store data or output stored data. Any such memory device may be configured as a volatile memory device in which stored data is not retained when the supply of power is interrupted, or be configured as a nonvolatile memory device in which stored data is retained even when the supply of power is interrupted.

The memory controller may control data communication between a host and the storage device.

The host may communicate with the memory device through the memory controller by using an interface protocol such as Peripheral Component Interconnect-Express (PCI-E), Advanced Technology Attachment (ATA), Serial ATA (SATA), Parallel ATA (PATA), or Serial Attached SCSI (SAS). Other interfaces for communication between the host and the memory system may also be used. Such interfaces include a Universal Serial Bus (USB), a Multi-Media Card (MMC), an Enhanced Small Disk Interface (ESDI), and Integrated Drive Electronics (IDE).

### SUMMARY

Embodiments provide a memory system for efficiently performing read reclaim, a memory controller of a memory system, and an operating method thereof.

In accordance with an aspect of the present disclosure, there is provided a memory system including: a memory device including a plurality of memory cells; and a memory controller configured to control the memory device to perform a plurality of read operations on memory cells in a selected physical page among the plurality of memory cells, calculate an inverted bit number representing different bit values, based on a plurality of read data received from the memory device, and perform a read reclaim operation on the selected physical page, based on the inverted bit number.

The memory controller may include: a command generator configured to generate first and second read commands for reading data of the selected physical page; an inverted cell information generator configured to generate inverted cell information based on first and second read data respectively corresponding to the first and second read commands; and a read reclaim controller configured to determine whether the read reclaim operation on the selected physical page is to be performed, based on the inverted cell information.

The inverted cell information generator may include: a first read data storage configured to store the first read data; a second read data storage configured to store the second read data; and an exclusive OR (XOR) operator configured to generate the inverted cell information by performing an XOR operation on the first read data and the second read data.

The read reclaim controller may include: an inverted bit counter configured calculate to the inverted bit number by counting a number of inverted bits in the inverted cell information; a threshold value storage configured to store a threshold value; a comparator configured to compare the inverted bit number with the threshold value; and a read reclaim determiner configured to determine whether the read reclaim operation on the physical page is to be performed, based on the comparison result of the comparator.

When the inverted bit number is greater than or equal to the threshold value as the comparison result of the comparator, the read reclaim determiner may determine that the read reclaim operation on the physical page is to be performed.

When the read reclaim determiner determines that the read reclaim operation on the physical page is to be performed, the memory controller may store data stored in the selected physical page in another physical page.

The memory controller may further include an internal memory configured to store an address mapping table including a mapping relationship between logical and physical addresses. When the read reclaim determiner determines that the read reclaim operation on the physical page is to be performed, the memory controller may update the address mapping table stored in the internal memory.

The memory controller may perform error correction on at least one of the first read data and the second read data and transfer the error-corrected data to a host.

In accordance with another aspect of the present disclosure, there is provided a memory controller for controlling a memory device under the control of a host, the memory controller including: a command generator configured to generate first and second read commands for controlling the memory device to repeatedly perform a read operation on a physical page, in response to a read request from the host; an inverted cell information generator configured to generate inverted cell information, based on first and second read data received from the memory device, respectively corresponding to the first and second read commands; and a read reclaim controller configured to generate a control signal for performing a read reclaim operation on the physical page, based on an inverted bit number included in the inverted cell information.

The inverted cell information generator may include: a first read data storage configured to store the first read data; a second read data storage configured to store the second read data; and an XOR operator configured to generate the inverted cell information by performing an XOR operation on the first read data and the second read data.

The read reclaim controller may include: an inverted bit counter configured to calculate the inverted bit number by counting a number of inverted bits in the inverted cell information; a threshold value storage configured to store a threshold value; a comparator configured to compare the inverted bit number with the threshold value; and a read reclaim determiner configured to determine whether the read reclaim operation on the physical page is to be performed based on the comparison result of the comparator.

When the inverted bit number is greater than or equal to the threshold value, the read reclaim determiner may generate a control signal to control the memory device to perform the read reclaim operation on the physical memory.

The memory controller may further include an internal memory configured to store an address mapping table. The address mapping table stored in the internal memory may be updated in response to the control signal.

In accordance with still another aspect of the present disclosure, there is provided a method for operating a memory controller, the method including: issuing a read command for repeatedly reading a selected page of a memory device, and receiving read data from the memory device; generating inverted cell information based on the read data; and determining whether a read reclaim operation on the selected page is to be performed, based on the inverted cell information.

The issuing of the read command and the receiving of the read data from the memory device may include: issuing a first read command for reading the selected page; receiving first read data corresponding to the first read command from the memory device; issuing a second read command for re-reading the selected page; and receiving second read data corresponding to the second read command.

The generating of the inverted cell information, based on the read data, may include generating the inverted cell information by performing an XOR operation on the first read data and the second read data.

The determining of whether the read reclaim operation on the selected page is to be performed may include: counting a number of bits of a first value, among two values, in the inverted cell information to generate a counted result; comparing the counted result with a threshold value; and determining whether the read reclaim operation on the selected page is to be performed, based on the comparison result.

The determining of whether the read reclaim operation on the selected page is to be performed, may include determining that the read reclaim operation on the selected page is to be performed when the counted result is greater than or equal to the threshold value.

In accordance with still another aspect of the present disclosure, there is provided a method for operating a memory system including a page, the method including: reading data first and second times from the page using a read voltage to generate first and second data respectively; comparing each value in the first data with a corresponding value in the second data to determine, for each pair of compared values, whether the values are the same or different; and performing a read reclaim operation on the page when it is determined that a number of pairs having different values is greater than or equal to a threshold.

### BRIEF DESCRIPTION OF THE DRAWINGS

Various embodiments will now be described more fully hereinafter with reference to the accompanying drawings; however, elements and features of the present invention may be configured or arranged differently than disclosed herein. Thus, the present invention is not limited to the embodiments set forth herein. Rather, these embodiments are provided so that this disclosure is thorough and complete and fully conveys the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system in accordance with an embodiment of the present disclosure.

FIG. 2 is a diagram illustrating a process of detecting an inverted cell when a read operation is performed twice according to Random Telegraph Noise (RTN).

FIG. 3 is a diagram illustrating an exemplary memory controller shown in FIG. 1.

FIG. 4 is a diagram illustrating a memory device in accordance with an embodiment of the present disclosure.

FIG. 5 is a diagram illustrating an exemplary memory block.

FIG. 6 is a diagram illustrating an embodiment of a three-dimensionally configured memory block.

FIG. 7 is a diagram illustrating another embodiment of the three-dimensionally configured memory block.

FIG. 8 is a block diagram illustrating an embodiment of an inverted cell information generator of FIG. 3.

FIG. 9 is a block diagram illustrating an embodiment of a read reclaim controller of FIG. 3.

FIG. 10 is a flowchart illustrating an operating method of the memory controller in accordance with an embodiment of the present disclosure.

FIG. 11 is a flowchart illustrating an embodiment of step S110 of FIG. 10.

FIG. 12 is a flowchart illustrating an embodiment of step S130 of FIG. 10.

FIG. 13A is a diagram illustrating read result data in accordance with an embodiment of the present disclosure.

FIG. 13B is a diagram illustrating inverted cell information generated from first and second read data in accordance with an embodiment of the present disclosure.

FIG. 14 is a diagram illustrating a distribution of numbers of inverted cells and a threshold voltage distribution of memory cells in accordance with embodiments of the present disclosure.

FIGS. 15A and 15B are diagrams illustrating a number of inverted cells according to a threshold voltage distribution state of a selected physical page in accordance with an embodiment of the present disclosure.

FIG. 16 is a flowchart illustrating an embodiment of step S150 of FIG. 10.

FIG. 17 is a diagram illustrating a memory device in accordance with an embodiment of the present disclosure.

FIG. 18 is a diagram illustrating another example of the memory system including the memory controller shown in FIGS. 1 and 2.

FIG. 19 is a diagram illustrating another example of the memory system including the memory controller shown in FIGS. 1 and 2.

FIG. 20 is a diagram illustrating another example of the memory system including the memory controller shown in FIGS. 1 and 2.

FIG. 21 is a diagram illustrating another example of the memory system including the memory controller shown in FIGS. 1 and 2.

### DETAILED DESCRIPTION

In the present disclosure, advantages, features and methods for achieving them will become more apparent after a reading of the following embodiments taken in conjunction with the drawings. Aspects of the present disclosure may, however, be modified in various ways, as would be apparent to those skilled in the art in light of the disclosed embodiments. Thus, the present invention is not limited to the embodiments set forth herein. Rather, these embodiments are provided to describe the present disclosure in detail to the extent that those skilled in the art to which the disclosure pertains may easily practice the present invention.

In the entire specification, when an element is referred to as being “connected” or “coupled” to another element, it can be directly connected or coupled to the another element or be indirectly connected or coupled to the another element with one or more intervening elements interposed therebetween. Communication between two elements, whether connected/coupled directly or indirectly, may be wired or wireless, unless the context indicates otherwise. In addition, when an element is referred to as “including” a component, this indicates that the element may further include one or more other components instead of excluding such component(s), unless the context indicates otherwise.

Various embodiments of the present disclosure will be described with reference to the accompanying drawings.

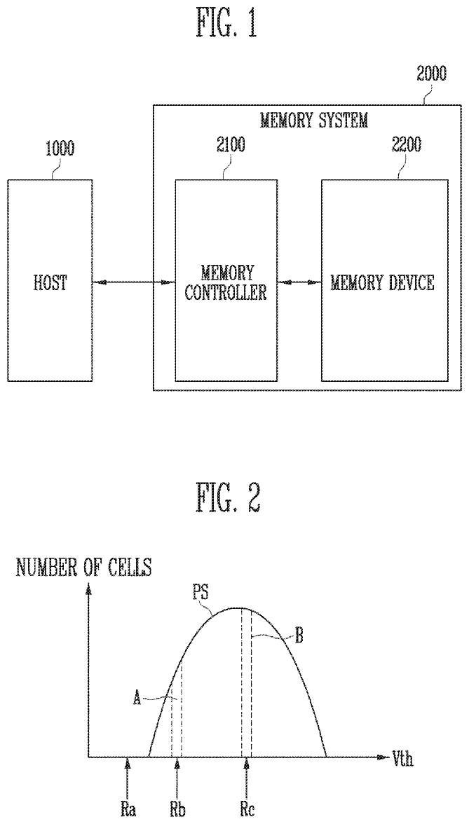

FIG. 1 is a diagram illustrating a memory system 2000 in accordance with an embodiment of the present disclosure.

Referring to FIG. 1, the memory system 2000 may include a memory device 2200 for storing data and a memory controller 2100 for controlling the memory device 2200 under the control of a host 1000.

The host 1000 may communicate with the memory system 2000 by using an interface protocol such as Peripheral Component Interconnect-Express (PCI-e), Advanced Technology Attachment (ATA), Serial ATA (SATA), Parallel ATA (PATA), or Serial Attached SCSI (SAS). Interface protocols between the host 1000 and the memory system 2000 are not limited to the above-described examples; any of various other interfaces, such as a Universal Serial Bus (USB), a Multi-Media Card (MMC), an Enhanced Small Disk Interface (ESDI), and Integrated Drive Electronics (IDE), may also be used.

The memory controller 2100 may control overall operations of the memory system 2000, and control data exchange between the host 1000 and the memory device 2200. For example, the memory controller 2100 may translate received information such that a command, an address, and data can be communicated between the host 1000 and the memory device 2200, and store and output the translated information. For example, in a program operation, the host 1000 may transfer a write request to the memory controller 2100. The memory controller 2100 may transmit a command, an address, data, and the like to the memory device 2200 in response to the received write request. For example, in a read operation, the host 1000 may transfer a read request to the memory controller 2100. The memory controller 2100 may transmit a command, an address, and the like to the memory device 2200 in response to the received read request.

The memory controller 2100 may perform error correction decoding on a codeword received from the memory device 2200. Hard decision decoding and/or soft decision decoding may be used as the error correction decoding. For example, any of a Bose, Chaudhri, Hocquenghem (BCH) code, a Reed Solomon code, a Reed Muller (RM) code, and a Hamming code may be used in the hard decision decoding. For example, any of Low Density Parity Check (LDPC) code and a convolution code may be used in the soft decision decoding. In an embodiment, the soft decision decoding may be performed when the hard decision decoding fails.

The memory device 2200 may be configured as a volatile memory device in which stored data is not retained when the supply of power is interrupted or a nonvolatile memory device in which stored data is retained even when the supply of power is interrupted. The memory device 2200 may perform a program operation, a read operation, an erase operation, a data compression operation, a copy-back operation, and the like under the control of the memory controller 2100.

The memory controller 2100 controls the memory device 2200 such that a read operation of memory cells is performed using different read voltages, and may control the memory device 2200 such that the read operation is repeatedly performed with respect to each of the same read voltages. That is, the memory controller 2100 may control the memory device 2200 to repeatedly perform the read operation with respect to one set of read voltages.

In a read operation of the memory system 2000, the memory controller 2100 may transfer a first read command to the memory device 2200. The memory device 2200 may perform a first read operation on a target physical page based on the received first read command. The memory device 2200 may transfer first read data that is data read as a result of the first read operation to the memory controller 2100.

The memory controller 2100 may temporarily store the received first data. The first read data may be in a state in which it is received from the memory device 2200, that is, data on which error correction and other decoding are not performed. The memory controller 2100 selectively performs error correction and other decoding on the received first read data and transfers the first read data to the host 1000.

Subsequently, the memory controller 2100 may transfer a second read command for the physical page that was the target of the first read operation to the memory device 2200. The memory device 2200 may perform a second read operation on the physical page that was the target of the first read operation, based on the received second read command. The memory device 2200 may transfer second read data that is data read as a result of the second read operation to the memory controller 2100.

The memory controller 2100 may temporarily store the received second read data. The memory controller 2100 may determine whether read reclaim is to be performed on the physical page by comparing the temporarily stored first and second read data.

In order to increase the probability that memory blocks will be uniformly worn in the memory device 2200, a wear leveling operation or a read reclaim operation may be performed. The read reclaim operation frees a logical block address from always having to be related to the same physical location or block by changing a physical location or block related to a specific logical block address (LBA). The block correlation of the LBA is changed, so that wear of a specific block can be reduced before another block is worn. In addition, when a read operation is performed plural times with respect to a physical location related to the specific LBA, the threshold voltage distribution of memory cells at the corresponding physical location may be deteriorated due to read disturb. When such a phenomenon is intensified, data cannot be recovered even by error correction. The read reclaim moves and stores, in another physical page, data of a physical page in which the threshold voltage distribution of memory cells is deteriorated, so that the phenomenon that error correction is impossible can be prevented.

More specifically, the memory controller 2100 may obtain an index indicating the location of an inverted cell of the corresponding physical page by comparing the first read data and the second read data. Also, the memory controller 2100 may calculate a number of inverted cells included in the corresponding physical page by comparing the first read data and the second read data.

In an embodiment, it may be determined whether a cell representing different bit values exist, by comparing the first and second read data received from the memory device 2200. Each cell having a different bit value from the first and second read data is determined as an inverted cell, and accordingly, a number of inverted cells can be calculated.

The memory controller 2100 may estimate a threshold voltage distribution of memory cells, based on the number of inverted cells, which is calculated through the above-described procedure. The number of memory cells in a threshold voltage distribution may be changed by Random Telegraph Noise (RTN) in every measurement. The RTN may mean noise of threshold voltage varied when a read operation is performed plural times using the same read voltage.

Therefore, the number of memory cells in a threshold voltage distribution, which is changed by the RTN whenever the read operation is performed plural times, may be in proportion to the threshold voltage distribution of the memory cells. When the number of memory cells having a specific threshold voltage is 1000, the number of memory cells, which is changed by the RTN, may be 100. When the number of memory cells having a specific threshold voltage is 100, the number of memory cells, which is changed by the RTN, may be 10. Therefore, in an embodiment, the calculated number of inverted cells may be used to estimate a threshold voltage distribution of memory cells.

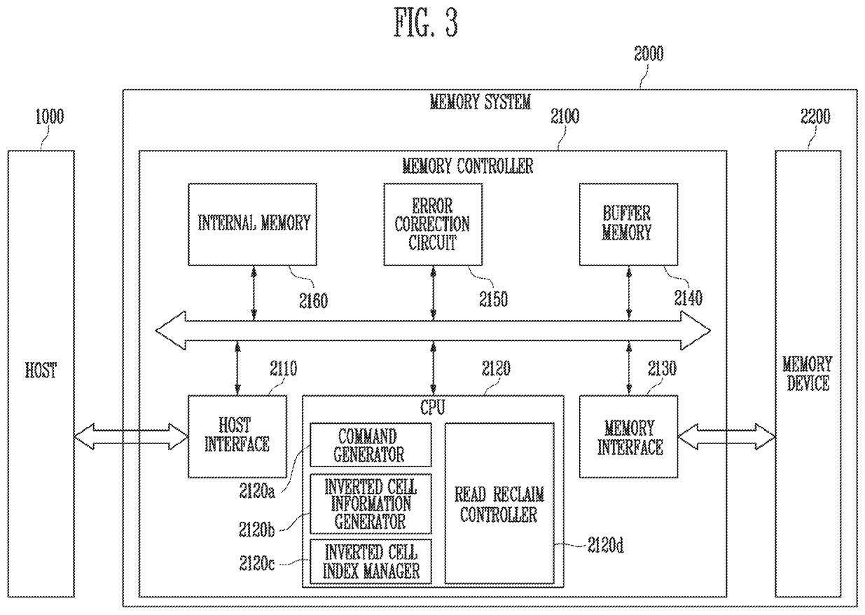

FIG. 2 is a diagram illustrating a process of detecting an inverted cell when a read operation is performed twice according to RTN.

Referring to FIG. 2, a threshold voltage distribution of memory cells included in a specific program state PS is illustrated. When the memory cells having the threshold voltage distribution shown in FIG. 2 are read using a read voltage Ra, all the memory cells are off. Therefore, when the memory cells are read using the read voltage Ra, no inverted cell is detected even though a read operation is performed plural times using the read voltage Ra.

When the read operation is performed on the memory cells having the threshold voltage distribution shown in FIG. 2 using a read voltage Rb, an inverted cell may be detected. When the memory cells are read using the read voltage Rb, memory cells having threshold voltages located to the right of the read voltage Rb are off, and memory cells having threshold voltages located to the left of the read voltage Rb are on. When the RTN is not considered, results obtained by performing the read operation twice using the read voltage Rb are to be equal to each other.

However, a result obtained by performing the read operation plural times using the read voltage Rb may be changed depending on influence of the RTN. In particular, in the case of memory cells in an area A, which have threshold voltages near the read voltage Rb, a read result may be changed in every measurement by the RTN. Accordingly, when the read operation is performed twice using the read voltage Rb, an inverted cell may be detected.

In addition, when the memory cells having the threshold voltage distribution shown in FIG. 2 are read using a read voltage Rc, a large number of inverted cells may be detected as compared with when the memory cells are read using the read voltage Rb. In the threshold voltage distribution of FIG. 2, a number of memory cells in an area B is larger than that of memory cells in the area A. Therefore, when the read operation is performed twice using the read voltage Rc, a large number of inverted cells may be detected as compared with when the read operation is performed twice using the read voltage Rb.

FIG. 3 is a diagram illustrating an exemplary memory controller, such as that shown in FIG. 1.

Referring to FIG. 3, the memory controller 2100 may include a host interface 2110, a Central Processing Unit (CPU) 2120, a memory interface 2130, a buffer memory 2140, an error correction circuit 2150, and an internal memory 2160. The host interface 2110, the error correction circuit 2150, the memory interface 2130, the buffer memory 2140, the error correction circuit 2150, and the internal memory 2160 may be controlled by the CPU 2120.

The host interface 2110 may exchange data with the host 1000, using a communication protocol.

The CPU 2120 may perform various calculations or generate a command and an address so as to control the memory device 2200. For example, the CPU 2120 may generate various commands necessary for a program operation, a read operation, an erase operation, a data compression operation, a copy-back operation, and the like.

In order to control an operation of the memory device 2200, the CPU 2120 may translate a logical address input from the host 1000 into a physical address, and transfer the physical address to the error correction circuit 2150. In some embodiments, the CPU 2120 may translate a logical address into a physical address or translate a physical address into a logical address, using an address mapping table stored in the buffer memory 2140.

The CPU 2120 may include a command generator 2120a, an inverted cell information generator 2120b, an inverted cell index manager 2120c, and a read reclaim controller 2120d.

The command generator 2120a may generate commands for controlling the memory device 2200 to perform various operations. In accordance with an embodiment of the present disclosure, the command generator 2120a may generate first and second read commands for controlling the memory device 2200 to perform first and second read operations on the same physical page twice.

In an embodiment, the command generator 2120a may generate a repetition read command and transfer the repetition read command to the memory device 2200. The repetition read command may be a read command instructing the memory device 2200 to perform the read operation on the same physical page plural times (e.g., twice). When the repetition read command is used, the command generator 2120a may generate one repetition read command and transfer the repetition read command to the memory device 2200. The memory device 2200 may perform the read operation on the same physical page plural times (e.g., twice), corresponding to the received repetition read command.

The inverted cell information generator 2120b may calculate inverted cell information, based on first and second read data received from the memory device 2200, corresponding to the first and second read commands. In an embodiment, the inverted cell information is data generated by performing a bitwise operation on the first and second read data, and may be data representing locations of inverted cells.

The inverted cell index manager 2120c may check an index of an inverted cell and store the checked index of the inverted cell. For example, the inverted cell index manager 2120c may store an index of an inverted cell corresponding to an optimum read voltage determined by the read reclaim controller 2120d. The index of the inverted cell corresponding to the optimum read voltage may be provided to the error correction circuit 2150 to perform error correction decoding.

The memory interface 2130 may communicate with the memory device 2200, using a communication protocol.

The buffer memory 2140 may temporarily store data while the memory controller 2100 is controlling the memory device 2200. For example, data received from the host 1000 until a program operation is completed may be temporarily stored in the buffer memory 2140. Also, data read from the memory device 2200 in a read operation may be temporarily stored in the buffer memory 2140.

The error correction circuit 2150 may perform error correction encoding and error correction decoding for error detection in a program operation or a read operation.

The internal memory 2160 may be used as a storage for storing various information required to operate the memory controller 2100. The internal memory 2160 may include a plurality of tables. For example, the internal memory 2160 may store a mapping table between logical and physical addresses.

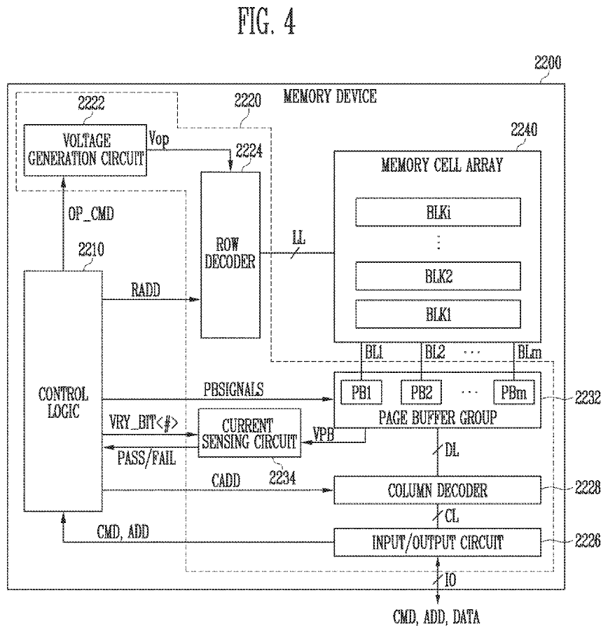

FIG. 4 is a diagram illustrating a memory device in accordance with an embodiment of the present disclosure. The memory device shown in FIG. 4 may be applied to the memory system shown in FIGS. 1 and 3.

The memory device 2200 may include control logic 2210, a peripheral circuit 2220, and a memory cell array 2240. The peripheral circuit 2220 may include a voltage generation circuit 2222, a row decoder 2224, an input/output circuit 2226, a column decoder 2228, a page buffer group 2232, and a current sensing circuit 2234.

The control logic 2210 may control the peripheral circuit 2220 under the control of the memory controller 2100 shown in FIG. 3.

The control logic 2210 may control the peripheral circuit 2220 in response to a command CMD and an address ADD, which are received from the memory controller 2100 through the input/output circuit 2226. For example, the control logic 2210 may output an operation signal OP_CMD, a row address RADD, page buffer control signals PBSIGNALS, and an allow bit VRY_BIT<#> in response to the command CMD and the address ADD. The control logic 2210 may determine whether a verify operation has passed or failed in response to a pass or fail signal PASS or FAIL received from the current sensing circuit 2234.

The control logic 2210 may control the peripheral circuit 2220 to perform a read operation when a first read command is received from the memory controller 2100 and transfer first read data that is a result obtained by performing the read operation to the memory controller 2100. Meanwhile, the control logic 2210 may control the peripheral circuit 2220 to perform a read operation when a second read command is received from the memory controller 2100 and transfer second read data that is a result obtained by performing the read operation to the memory controller 2100.

The peripheral circuit 2220 may perform a program operation for storing data in the memory cell array 2240, a read operation for outputting data stored in the memory cell array 2240, and an erase operation for erasing data stored in the memory cell array 2240.

The voltage generation circuit 2222 may generate various operating voltages Vop used in program, read, and erase operations in response to the operation signal OP_CMD received from the control logic 2210. For example, the voltage generation circuit 2222 may transfer a program voltage, a verify voltage, a pass voltage, a read voltage, an erase voltage, a turn-on voltage, and the like to the row decoder 2224.

The row decoder 2224 may transfer the operating voltages Vop to local lines LL connected to a selected memory block among memory blocks of the memory cell array 2240 in response to the row address RADD received from the control logic 2210. The local lines LL may include local word lines, local drain select lines, and local source select lines. In addition, the local lines LL may include various lines such as a source line, which are connected to the memory block.

The input/output circuit 2226 may transfer the command CMD and the address ADD, which are received from the memory controller 2100, to the control logic 2210 through input/output lines IO, or exchange data DATA with the column decoder 2228.

The column decoder 2228 may transfer data between the input/output circuit 2226 and the page buffer group 2232 in response to a column address CADD received from the control logic 2210. For example, the column decoder 2228 may exchange data with page buffers PB1 to PBm through data lines DL, or exchange data with the input/output circuit 2226 through column lines CL.

The page buffer group 2232 may be connected to bit lines BL1 to BLm commonly connected to memory blocks BLK1 to BLKi. The page buffer group 2232 may include a plurality of page buffers PB1 to PBm connected to the bit lines BL1 to BLm. For example, one-page buffer may be connected to each of the bit lines. The page buffers PB1 to PBm may operate in response to the page buffer control signals PBSIGNALS received from the control logic 2210. For example, in a program operation, the page buffers PB1 to PBI may temporarily store program data received from the memory controller 2100, and adjust a voltage applied to the bit lines BL1 to BLm according to the program data. Also, in a read operation, the page buffers PB1 to PBI may temporarily store data received through the bit lines BL1 to BLm, or sense a voltage or current of the bit lines BL1 to BLm.

In a read or verify operation, the current sensing circuit 2234 may generate a reference current in response to the allow bit VRY_BIT<#> received from the control logic 2210, and output a pass or fail signal PASS or FAIL by comparing a sensing voltage VPB received from the page buffer group 2232 with a reference voltage generated by the reference current.

The memory cell array 2240 may include a plurality of memory blocks BLK1 to BLKi in which data is stored. User data and various information required to perform an operation of the memory device 2200 may be stored in the memory blocks BLK1 to BLKi. The memory blocks BLK1 to BLKi may be implemented in a two-dimensional structure or a three-dimensional structure, and be configured identical to one another.

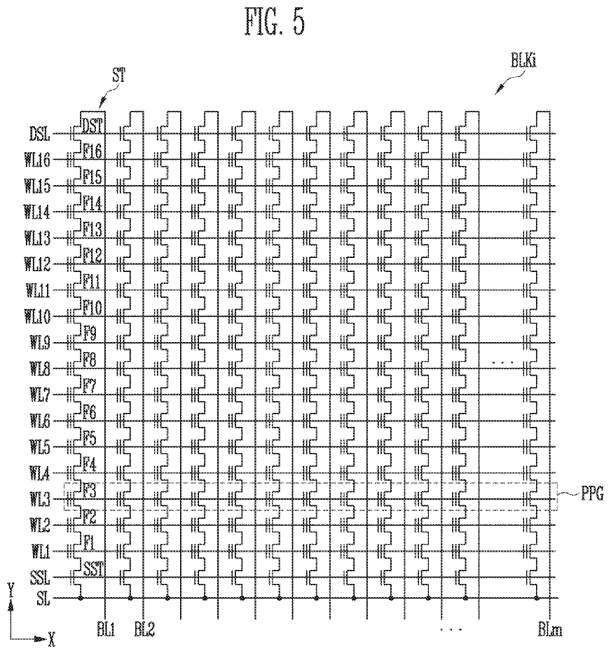

FIG. 5 is a diagram illustrating an exemplary memory block BLKi.

A memory cell array may include a plurality of memory blocks. Memory block BLKi illustrated in FIG. 5 is representative of any of the plurality of blocks.

In the memory block BLKi, a plurality of word lines arranged in parallel to one another may be connected between a first select line and a second select line. The first select line may be a source select line SSL, and the second select line may be a drain select line DSL. Specifically, the memory block BLKi may include a plurality of strings ST connected between bit lines BL1 to BLn and a source line SL. The bit lines BL1 to BLn may be connected to the strings ST, respectively, and the source line SL may be commonly connected to the strings ST. The strings ST may be configured identically to one another, and therefore, a string ST connected to a first bit line BL1 will be described in detail as an example.

The string ST may include a source select transistor SST, a plurality of memory cells F1 to F16, and a drain select transistor DST, which are connected in series to each other between the source line SL and the first bit line BL1. At least one source select transistor SST and at least one drain select transistor DST may be included in one string ST. Also, more than the 16 memory cells F1 to F16 shown in the drawing may be included in one string ST.

A source of the source select transistor SST may be connected to the source line SL, and a drain of the drain select transistor DST may be connected to the first bit line BL1. The memory cells F1 to F16 may be connected in series between the source select transistor SST and the drain select transistor DST. Gates of source select transistors SST included in different strings ST may be connected to the source select line SSL, gates of drain select transistors DST included in different strings ST may be connected to the drain select line DSL, gates of the memory cells F1 to F16 included in different strings ST may be connected to a plurality of word lines WL1 to WL16. A group of memory cells connected to the same word line among the memory cells included in different strings ST may be a physical page PPG. Therefore, physical pages PPG of which number corresponds to that of the word lines WL1 to WL16 may be included in the memory block BLKi.

One memory cell may store data of one bit. This is called as a single level cell (SLC). One physical page PPG may store one logical page (LPG) data. The one LPG data may include data bits of which number corresponds to that of cells included in one physical page PPG. For example, when data of two or more bits is stored in one memory cell, one physical page PPG may store two or more LPG data. For example, in a memory device driven in an MLC type, two LPG data may be stored in one physical page PPG. In a memory device driven in a TLC type, three LPG data may be stored in the one physical page PPG.

FIG. 6 is a diagram illustrating an embodiment of a three-dimensionally configured memory block.

The memory cell array 2240 may include a plurality of memory blocks BLK1 to BLKi. A first memory block BLK1, which is representative, will be described as an example. The first memory block BLK1 may include a plurality of strings ST11 to STim and ST21 to ST2m. In an embodiment, each of the plurality of strings ST11 to STim and ST21 to ST2m may be formed in a ‘U’ shape. In the first memory block BLK1, m strings may be arranged in a row direction (X direction). For clarity, FIG. 6 illustrates two strings arranged in a column direction (Y direction); however, three or more strings may be arranged in the column direction (Y direction).

Each of the plurality of strings ST11 to ST1m and ST21 to ST2m may include at least one source select transistor SST, first to nth memory cells MC1 to MCn, a pipe transistor PT, and at least one drain select transistor DST.

The source and drain select transistors SST and DST and the memory cells MC1 to MCn may have structures similar to one another. For example, each of the source and drain select transistors SST and DST and the memory cells MC1 to MCn may include a channel layer, a tunnel insulating layer, a charge trapping layer, and a blocking insulating layer. For example, a pillar for providing the channel layer may be provided in each string. For example, a pillar for providing at least one of the channel layers, the tunnel insulating layer, the charge trapping layer, and the blocking insulating layer may be provided in each string.

The source select transistor SST of each string may be connected between a source line SL and memory cells MC1 to MCp.

In an embodiment, source select transistors of strings arranged in the same row may be connected to a source select line extending in the row direction, and source select transistors of strings arranged in different rows may be connected to different source select lines. In FIG. 6, source select transistors of strings ST11 to STim of a first row may be connected to a first source select line SSL1. Source select transistors of strings ST21 to ST2m of a second row may be connected to a second source select line SSL2.

In another embodiment, the source select transistors of the strings ST11 to ST1m and ST21 to ST2m may be commonly connected to one source select line.

First to nth memory cells MC1 to MCn of each string may be connected between the source select transistor SST and the drain select transistor DST.

The first to nth memory cells MC1 to MCn may be divided into first to pth memory cells MC1 to MCp and (p+1)th to nth memory cells MCp+1 to MCn. The first to pth memory cells MC1 to MCp may be sequentially arranged in a vertical direction (Z direction), and be connected in series to each other between the source select transistor SST and the pipe transistor PT. The (p+1)th to nth memory cells MCp+1 to MCn may be sequentially arranged in the vertical direction (Z direction), and be connected in series to each other between the pipe transistor PT and the drain select transistor DST. The first to pth memory cells MC1 to MCp and the (p+1)th to nth memory cells MCp+1 to MCn may be connected to each other through the pipe transistor PT. Gates of the first to nth memory cells MC1 to MCn of each string may be connected to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. A gate of the pipe transistor PT of each string may be connected to a pipe line PL.

The drain select transistor DST of each string may be connected to a bit line and the memory cells MCp+1 to MCn. Strings arranged in the row direction may be connected to a drain select line extending in the row direction. Drain select transistors of the strings ST11 to ST1, of the first row may be connected to a first drain select line DSL1. Drain select transistors of the strings ST21 to ST2m of the second row may be connected to a second drain select line DSL2.

Strings arranged in the column direction may be connected to bit lines extending in the column direction. In FIG. 6, strings ST11 and ST21 of a first column may be connected to a first bit line BL1. Strings ST1m and ST2m of an mth column may be connected to an nth bit line BLn.

Memory cells connected to the same word line among the strings arranged in the row direction may constitute one page. For example, memory cells connected to the first word line WL1 among the strings ST11 to ST1m of the first row may constitute one page. Memory cells connected to the first word line WL1 among the strings ST21 to ST2m of the second row may constitute another page. When any one of the drain select lines DSL1 and DSL2 is selected, strings arranged in one row direction may be selected. When any one of the word lines WL1 to WLn is selected, one page among the selected strings may be selected.

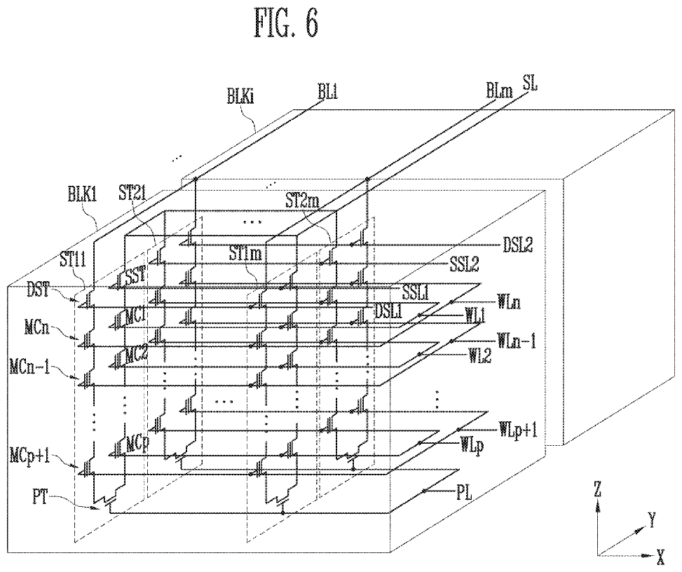

FIG. 7 is a diagram illustrating another embodiment of the three-dimensionally configured memory block.

The memory cell array 2240 may include a plurality of memory blocks BLK1 to BLKi. A first memory block BLK1, which is representative, will be described as an example. The first memory block BLK1 may include a plurality of strings ST11′ to ST1m′ and ST21′ to ST2m′. Each of the plurality of strings ST11′ to ST1m′ and ST21′ to ST2m′ may extend along a vertical direction (Z direction). In the first memory block BLK1, m strings may be arranged in a row direction (X direction). FIG. 7 illustrates two strings arranged in a column direction (Y direction); however, three or more strings may be arranged in the column direction (Y direction).

Each of the plurality of strings ST11′ to ST1m′ and ST21′ to ST2m′ may include at least one source select transistor SST, first to nth memory cells MC1 to MCn, and at least one drain select transistor DST.

The source select transistor SST of each string may be connected between a source line SL and the memory cells MC1 to MCn. Source select transistors of strings arranged in the same row may be connected to the same source select line. Source select transistors of strings ST11′ to ST1m′ arranged on a first row may be connected to a first source select line SSL1. Source select transistors of strings ST21′ to ST2m′ arranged on a second row may be connected to a second source select line SSL2. In another embodiment, the source select transistors of the strings ST11′ to ST1m′ and ST21′ to ST2m′ may be commonly connected to one source select line.

The first to nth memory cells MC1 to MCn of each string may be connected in series to each other between the source select transistor SST and the drain select transistor DST. Gates of the first to nth memory cells MC1 to MCn may be connected to first to nth word lines WL1 to WLn, respectively.

In an embodiment, at least one of the first to nth memory cells MC1 to MCn may be used as a dummy memory cell. When a dummy memory cell is provided, the voltage or current of a corresponding string can be stably controlled. Accordingly, the reliability of data stored in the first memory block BLK1 can be improved.

The drain select transistor DST of each string may be connected between a bit line and the memory cells MC1 to MCn. Drain select transistors DST of strings arranged in the row direction may be connected to a drain select line extending in the row direction. The drain select transistors DST of the strings ST11′ to ST1m′ of the first row may be connected to a first drain select line DSL1. The drain select transistors DST of the strings ST21′ to ST2m′ of the second row may be connected to a second drain select line DSL2.

That is, the first memory block BLK1 of FIG. 7 may have a circuit identical to that of the first memory block BLK1 of FIG. 6, except that the pipe transistor PT is excluded from each string.

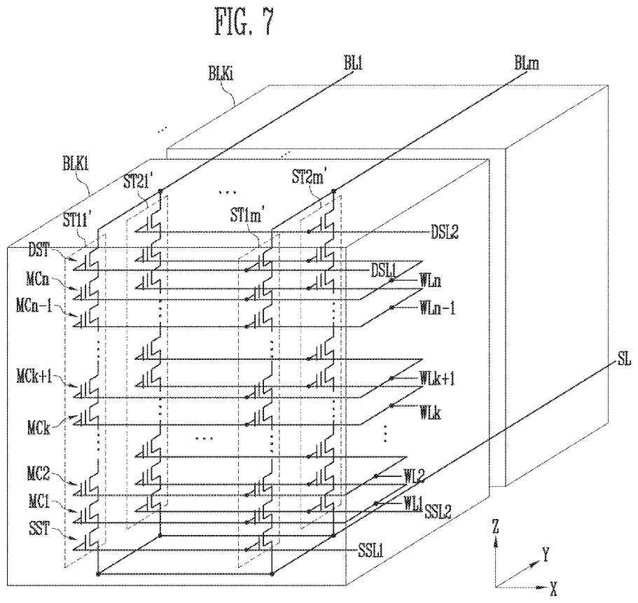

FIG. 8 is a block diagram illustrating an embodiment of the inverted cell information generator 2120b of FIG. 3.

Referring to FIG. 8, the inverted cell information generator 2120b may include a first read data storage 2121, a second read data storage 2122, and an XOR operator 2123.

The first read data storage 2121 stores first read data RD1 received from the memory device 2200, corresponding to a first read command. The second read data storage 2122 stores second read data RD2 received from the memory device 2200, corresponding to a second read command. Each of the first and second read data storages 2121 and 2122 may be implemented with a register. FIGS. 3 and 8 illustrate an arrangement in which the first and second read data storages 2121 and 2122 are included in the CPU 2120. However, in some embodiments, each of the first and second read data storages 2121 and 2122 may be implemented with a register configured separately and disposed externally to the CPU 2120. In another embodiment, the first and second read data storages 2121 and 2122 may be included in the internal memory 2160.

As described above, the first and second read commands are for reading the same physical page of the memory device 2200. Therefore, when no memory cell having a threshold voltage near a read voltage used in a read operation exists, the first read data and the second read data may include the same bit data. When a memory cell having a threshold voltage near the read voltage used in the read operation exists, the first read data and the second read data may include bit data having different values.

The XOR operator 2123 may generate inverted cell information or data ICD by performing an exclusive OR (XOR) operation on the first read data RD1 and the second read data RD2. When bits of the first read data RD1 and the second read data RD2 are equal to each other, a bit of the corresponding inverted cell data ICD has a value of 0 through the XOR operation. On the other hand, when the bits of the first read data RD1 and the second read data RD2 are different from each other, the bit of the corresponding inverted cell data ICD has a value of 1 through the XOR operation.

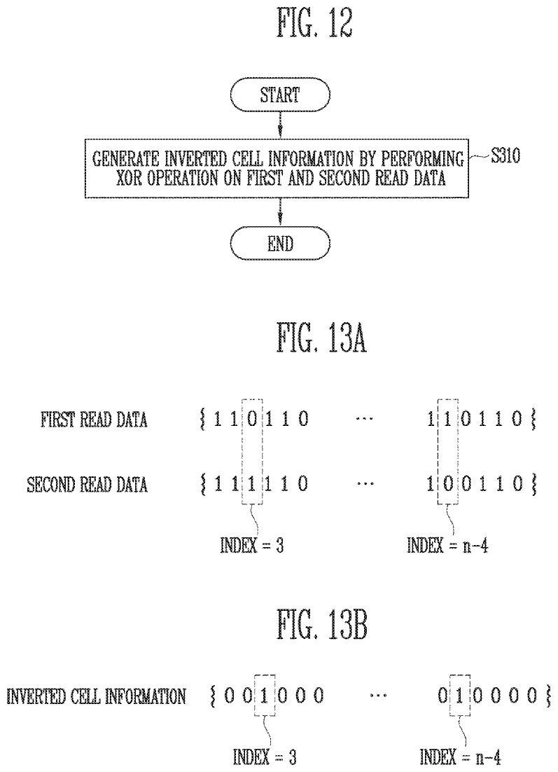

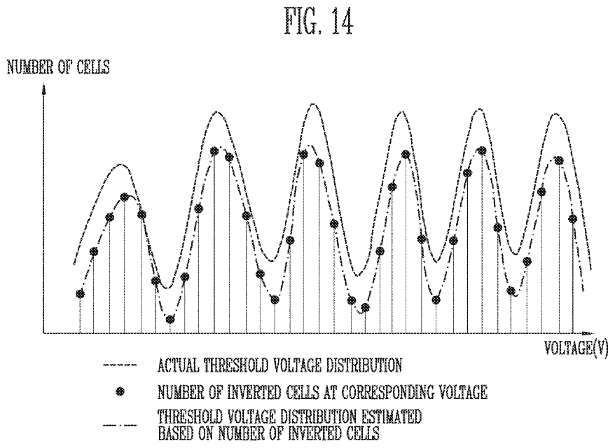

An example of the first and second read data RD1 and RD2 and the inverted cell information ICD will be described later with reference to FIGS. 13A and 13B.

FIG. 9 is a block diagram illustrating an embodiment of the read reclaim controller 2120d of FIG. 3.

Referring to FIG. 9, the read reclaim controller 2120d may include an inverted bit counter 2125, a threshold value storage 2126, a comparator 2127, and a read reclaim determiner 2128.

The inverted bit counter 2125 may receive inverted cell information ICD from the inverted cell information generator 2120b. The inverted bit counter 2125 generates an inverted bit number IBN by counting a number of “l's” in the received inverted cell information ICD. Each “1” in the ICD represents one bit that has flipped from one read operation to the next.

As described above, when a memory cell having a threshold voltage near a read voltage used in a read operation exists, a result obtained by reading the corresponding memory cell may be changed by the RTN whenever the read operation is repeated. That is, a bit flip may occur with respect to data of a specific memory cell while the read operation is performed again.

When the number of bits, the value of which has flipped, is 0 or a small value, this means that no memory cell having a threshold voltage near the read voltage exists or that the number of such memory cells is small. That is, this means that the threshold voltage distribution of a physical page that is target on which the read operation is performed is satisfactory. When the number of bits that flipped is a large value, this means that the number of memory cells having threshold voltages near the read voltage is large. That is, this means that the threshold voltage distribution of a physical page that is a target on which the read operation is performed is deteriorated. The memory controller 2100 in accordance with an embodiment of the present disclosure determines whether read reclaim is to be performed by counting the number of bits of value “1” in the inverted cell information ICD, i.e., the number of bit flips.

The threshold value storage 2126 stores a threshold value THR which serves as a reference as to whether the read reclaim is to be performed. The threshold value storage 2126 may be implemented with a register. According to FIGS. 3 and 9, a case where the threshold value storage 2126 is included in the CPU 2120 is illustrated. However, in some embodiments, the threshold value storage 2126 may be implemented with a register configured separately and externally to the CPU 2120. In another embodiment, the threshold value storage 2126 may be included in the internal memory 2160.

The comparator 2127 may generate a result value RSLT by comparing the inverted bit number IBN received from the inverted bit counter 2125 and the threshold value THR received from the threshold value storage 2126. For example, when the inverted bit number IBN is greater than or equal to the threshold value THR, the comparator 2127 may generate a result value RSLT having a value of “0.” When the inverted bit number IBN is less than the threshold value THR, the comparator 2127 may generate a result value RSLT having a value of “1.” However, this is merely illustrative, and a specific value of the result value RSLT may be determined in another manner.

The generated result value RSLT is transferred to the read reclaim determiner 2128. The read reclaim determiner 2128 determines whether read reclaim on a physical page, which is a target on which first and second read operations are performed, is to be performed, based on the result value RSLT. In an example, when the result RSLT having a value of “0” or representing that the inverted bit number IBN is greater than or equal to the threshold value THR is received as the comparison result of the comparator 2127, the read reclaim determiner 2128 may generate a control signal RC for starting a read reclaim operation on the corresponding physical page. On the other hand, when the result RSLT having a value of “1” or representing that the inverted bit number IBN is less than the threshold value THR is received as the comparison result of the comparator 2127, the read reclaim determiner 2128 may not perform any operation. Therefore, the read reclaim operation on the corresponding physical page is not performed.

The memory controller 2100 may control the memory device 2200 to program data stored in the selected physical page to another physical location in response to the control signal RC for starting the read reclaim operation. In conjunction with this, the memory controller 2100 may update an address mapping table stored in the internal memory 2160.

The memory controller 2100 may determine whether the read reclaim is to be performed, based on first and second read data. The memory controller 2100 may perform error correction on at least one of the received first and second read data and transfer the error-corrected data to the host 1000.

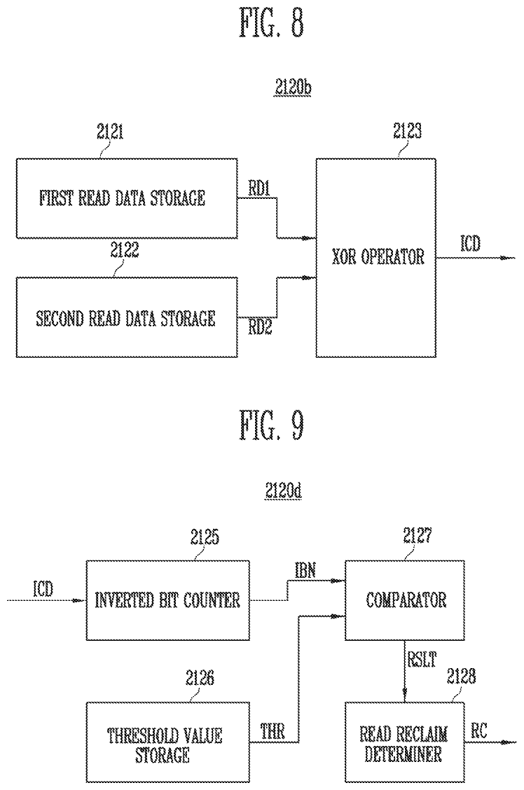

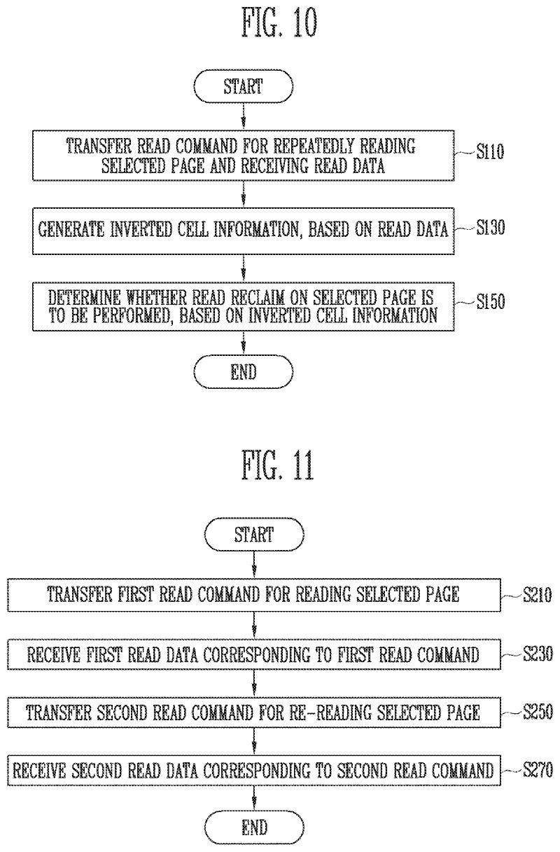

FIG. 10 is a flowchart illustrating an operating method of the memory controller 2100 in accordance with an embodiment of the present disclosure.

Referring to FIG. 10, the operating method of the memory controller 2100 may include a step (S110) of transferring a read command for repeatedly reading a selected page using the same read voltage to the memory device 2200 and receiving read data from the memory device 2200, a step (S130) of generating inverted cell information ICD based on the received read data, and a step (S150) of determining whether read reclaim on the selected page is to be performed based on the inverted cell information ICD.

In the step S110, a general read command may be transferred twice or more to the memory device 2200 so as to repeatedly read the selected page using the same read voltage. In this process, first read data may be received after a first read command is transferred to the memory devices 2200, and second read data may be received after a second read command is transferred to the memory device 2200. An embodiment of the step S110 will be described in more detail later with reference to FIG. 11.

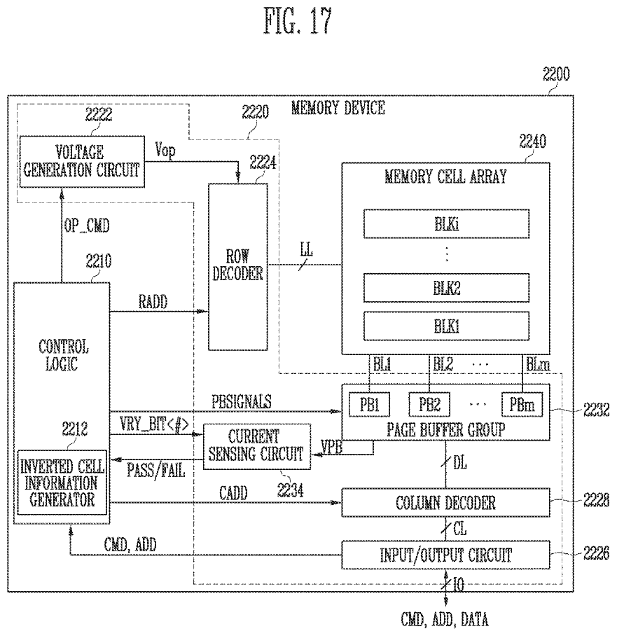

In another embodiment, a repetition read command may be transferred to the memory device 2200 in the step S110. The memory device 2200 may perform a read operation on the selected page plural times (e.g., twice or more) using the same read voltage in response to the repetition read command. This embodiment will be described later with reference to FIG. 17.

In the step S130, inverted cell information is generated based on the read data. A more detailed description of the step S130 will be given later with reference to FIG. 12.

In the step S150, it is determined whether read reclaim on the selected page is to be performed based on the generated inverted cell information ICD. More specifically, when the number of inverted bits included in the inverted cell information is large, it may be determined that a read reclaim operation on the selected page is to be performed. When the number of inverted bits included in the inverted cell information is small, it may be determined that the read reclaim operation is not to be performed. A detailed description of the step S150 will be given later with reference to FIG. 16.

FIG. 11 is a flowchart illustrating an embodiment of the step S110 of FIG. 10.

Referring to FIG. 11, first, the memory controller 2100 transfers a first read command for reading a selected page using a predetermined read voltage to the memory device 2200 (S210). The memory device 2200 may perform a read operation on the selected page based on the first read command. The memory controller 2100 receives, from the memory device 2200, first read data that is a result obtained by performing the read operation, based on the first read command (S230). As shown in FIG. 8, the received first read data RD1 may be stored in the first read data storage 2121.

Selectively, in step S230, the received first read data may be transferred to the host 1000. Since the first read data is data on which error correction and other decoding are not performed, the first read data may be transferred to the host 1000 after the error correction and other decoding on the first read data are performed.

The memory controller 2100 transfers a second read command for re-reading the selected page using the same read voltage to the memory device 2200 (S250). An address corresponding to the first read command and an address corresponding to the second read command are the same. That is, a page on which a first read operation corresponding to the first read command is to be performed is identical to that on which a second read operation corresponding to the second read command is to be performed. The memory device 2200 may perform a read operation on the selected page using the same read voltage based on the second read command. The memory controller 2100 receives, from the memory device 2200, second read data that is a result obtained by performing the read operation, based on the second read command (S270). As shown in FIG. 8, the received read data RD2 may be stored in the second read data storage 2122.

Selectively, the second read data received in the step S270 may be transferred to the host 1000. Since the second read data is data on which error correction and other decoding are not performed, the second read data may be transferred to the host 1000 after the error correction and other decoding on the second read data are performed.

In an embodiment, when the first read data is transferred to the host 1000 in the step S230, the second read data may not be transferred to the host 1000 in the step S270. Also, when the first read data is not transferred to the host 1000 in the step S230, at least one of the first and second read data may be transferred to the host 1000 in the step S270.

An example of the first read data received in the step S230 and the second read data received in the step S270 will be described later with reference to FIG. 13A.

FIG. 12 is a flowchart illustrating an embodiment of the step S130 of FIG. 10.

Referring to FIG. 12, the step (S130) of generating inverted cell information, based on the read data, includes a step (S310) of generating inverted cell information by performing an XOR operation on the received first and second read data. An example of the first and second read data and the inverted cell information will be described later with reference to FIGS. 13A and 13B.

FIG. 13A is diagram illustrating read result data in accordance with an embodiment of the present disclosure.

In FIG. 13A, a case where first read data corresponding to the first read command and second read data corresponding to the second read command are received is illustrated as an example.

Referring to FIG. 13A, it can be seen that first read data (110110 . . . 110110) corresponding to the first read command has been received and second read data (111110 . . . 110110) corresponding to the second read command has been received.

When comparing the first read data and the second read data on a bitwise basis, it can be seen that bits of cells corresponding to a third index and an (n−4)th index have been inverted. As shown in FIG. 13A, an inverted cell represents a memory cell in which the bit value in the first data is different than the corresponding bit value in the second read data.

FIG. 13B is a diagram illustrating inverted cell data or information ICD generated from the first and second read data.

In FIG. 13B, in an example, each inverted cell is designated as ‘1,’ and each non-inverted cell is designated as ‘0.’ Referring to the first and second read data of FIG. 13A together, when a memory cell has the same bit in the first and second data, a corresponding index of the inverted cell information has a bit value of 0. On the other hand, when the memory cell has different bits in the first and second data, a corresponding index of the inverted cell information has a bit value of 1. Thus, it can be seen that the inverted cell information ICD is generated by performing a bitwise operation on the first and second read data shown in FIG. 13A. More specifically, the inverted cell information ICD may be generated by performing an XOR operation on the values of each bit pair, that is a bit in the first read data and the corresponding bit in the second read data. When the values of a bit pair are equal, the corresponding bit of the inverted cell information has a value of 0 as a result of the XOR operation. When the values of a bit pair are different from each other, the bit of the inverted cell information has a value of 1 through the XOR operation.

Therefore, the memory controller 2100 may generate inverted cell information ICD with reference to the first and second read data received from the memory device 2200, and additionally check indices of the inverted cell information ICD. For example, the memory controller 2100 may determine that a bit designated as ‘1’ among the bits in the inverted cell information ICD corresponds to the inverted cell, and determine that a bit designated as ‘0’ does not correspond to the inverted cell. The memory controller 2100 may calculate a number of inverted cells by counting a number of bits of ‘1.’

Throughout this specification, it has been described that inverted cell information ICD is generated by performing an XOR operation on first and second read data. However, this is merely illustrative; the inverted cell information may be generated by performing an exclusive NOR (XNOR) operation on the first and second read data. The memory controller 2100 may calculate a number of inverted cells by counting a number of bits of ‘0.’

FIG. 14 is a diagram illustrating a distribution of numbers of inverted cells and a threshold voltage distribution of memory cells in accordance with embodiments of the present disclosure.

In FIG. 14, there are illustrated an actual threshold voltage distribution of a plurality of memory cells and a threshold voltage distribution estimated from a calculated number of inverted cells when a read operation is performed using various read voltages.

Referring to FIG. 14, it can be seen that the actual threshold voltage and the distribution of inverted cells almost correspond to each other. Thus, it can be seen that the threshold voltage distribution of a corresponding physical page is deteriorated when the number of inverted cells increases as a result obtained by performing a read operation plural times, using a currently used read voltage. Accordingly, the memory controller 2100 may perform read reclaim based on the number of inverted cells.

Additionally, the memory controller 2100 may estimate a threshold voltage distribution based on the number of inverted cells, and search for a valley of the estimated threshold voltage distribution. Also, the memory controller 2100 may set a voltage corresponding to the valley as an optimum read voltage.

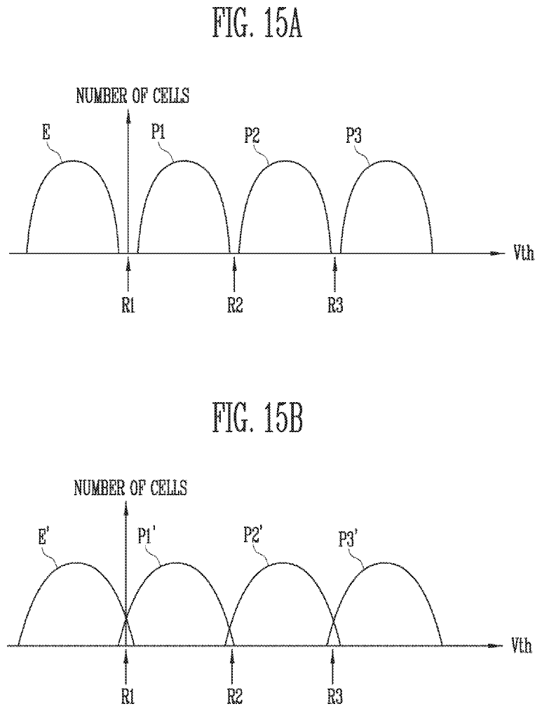

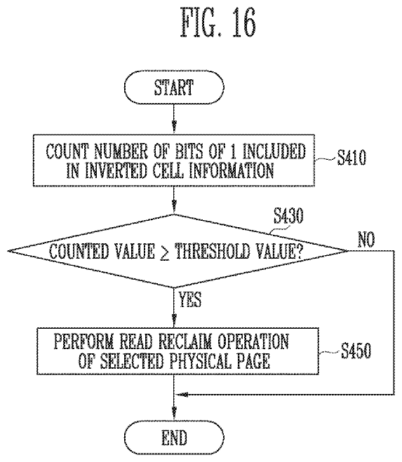

FIGS. 15A and 15B are diagrams illustrating a number of inverted cells according to a threshold voltage distribution state of a selected physical page.

Referring to FIG. 15A, a threshold voltage distribution just after a selected physical page is programmed is illustrated as an example. Memory cells included in the physical page have a threshold voltage belonging to any one of an erase state E and first to third program states P1, P2, and P3. A read operation on the selected physical page is performed according to first to third read voltages R1, R2, and R3.

The threshold voltage of FIG. 15A is in a satisfactory state, and no memory cell having a threshold voltage near the first to third read voltages R1, R2, and R3 exists. Accordingly, as described with reference to FIG. 2, although the read operation is repeatedly performed through the first to third read voltages R1, R2, and R3, read results are the same. This is because no memory cell having a threshold voltage adjacent to the read voltage, with respect to which a bit flip occurs due to RTN, exists.

Thus, in the case of the threshold voltage distribution shown in FIG. 15A, first and second read data are the same, and all bits of inverted cell information have a value of ‘0.’

Referring to FIG. 15B, a threshold voltage distribution after a selected physical page is programmed and a read operation is then repeated is illustrated as an example. Memory cells included in the physical page have a threshold voltage belonging to any one of an erase state E′ and first to third program states P1′, P2′, and P3′. The read operation on the selected physical page is performed according to the first to third read voltages R1, R2, and R3.

As the read operation on the physical page is repeated, the threshold voltage distribution of each of the states is further widened due to read disturb. Accordingly, as shown in FIG. 15B, threshold voltages of adjacent states overlap.

As the threshold voltage distribution is deteriorated, a memory cell having a threshold voltage near the first to third read voltages exists. Accordingly, as described with reference to FIG. 2, when the read operation is repeatedly performed through the first to third read 1.5 voltages R1, R2, and R3, a bit flip occurs due to RTN.

Thus, in the case of the threshold voltage distribution shown in FIG. 15B, first and second read data includes different bits, and some bits of inverted cell information ICD have a value of ‘1.’ When the threshold voltage distribution is further deteriorated, the number of different bits in the first and second read data may increase, and as a result, the number of bits of ‘1’ included in the inverted cell information ICD may increase.

Thus, according to the memory system 2000, the memory controller 2100, and the operating method thereof in accordance with embodiments of the present disclosure, inverted cell information ICD is generated by comparing first and second read data obtained by repeatedly performing a read operation on the same physical page using the same read voltage, identifying each corresponding bit pair having different values with a number, e.g., 1, to generate inverted cell information ICD, and counting the number of 1's in the inverted cell information ICD. In addition, when the number of 1's in the ICD is greater than or equal to a threshold value, which may be predetermined and indicate that a threshold voltage distribution has been considerably deteriorated due to read disturb, a read reclaim operation is performed. Accordingly, the read reclaim operation on a specific physical page of the memory device 2200 can be more efficiently performed.

FIG. 16 is a flowchart illustrating an embodiment of the step S150 of FIG. 10.

Referring to FIG. 16, the step (S150) of determining whether the read reclaim of the selected physical page is to be performed based on the inverted cell information ICD, may include a step (S410) of counting a number of l's in the inverted cell information ICD, a step (S430) of comparing the counted value with a threshold value, and a step (S450) of performing a read reclaim operation of the selected physical page when the counted value is greater than or equal to the threshold value.

The step S410 may be performed by the inverted bit counter 2125 of FIG. 9. The inverted bit counter 2125 may transfer, as the counted value, an inverted bit number IBN generated by counting a number of bits of 1 included in the inverted cell information ICD to the comparator 2127.

The step S430 may be performed by the comparator 2127 of FIG. 9. The comparator 2127 may compare the inverted cell information ICD and a threshold value THR stored in the threshold value storage 2126.

The step S450 may be performed by the read reclaim determiner 2128 of FIG. 9. When the counted value, i.e., the inverted bit number INB is greater than or equal to the threshold value THR, the read reclaim determiner 2128 may generate a control signal RC for determining that the read reclaim operation of the selected physical page is to be performed. The memory controller 2100 may control the memory device 2200 to perform the read reclaim operation of the selected physical page in response to the control signal RC.

FIG. 17 is a diagram illustrating the memory device 2200 in accordance with another embodiment of the present disclosure. The memory device 2200 shown in FIG. 17 may be applied to the memory system shown in FIGS. 1 and 3.

The memory device 2200 may include control logic 2210, a peripheral circuit 2220, and a memory cell array 2240. The peripheral circuit 2220 may include a voltage generation circuit 2222, a row decoder 2224, an input/output circuit 2226, a column decoder 2228, a page buffer group 2232, and a current sensing circuit 2234. The other components except the control logic 2210 are substantially identical to those of the memory device shown in FIG. 4, and therefore, overlapping description thereof is omitted here.

The control logic 2210 may include an inverted cell information generator 2212. When the memory device 2200 receives a repetition read command from the memory controller 2100, the control logic 2210 may control the peripheral circuit 2220 to repeatedly perform a read operation on a selected physical page using the same read voltage. Accordingly, the peripheral circuit 2220 may perform the read operation on the selected physical page of the memory cell array 2240 multiple times using the same read voltage. For example, the control logic 2210 may control the peripheral circuit 2220 to perform the read operation on the selected physical page twice using the same read voltage. The inverted cell information generator 2212 may generate inverted cell information ICD, based on first and second read data that are results obtained by performing the read operation twice. The inverted cell information generator 2212 may be configured substantially identically to the inverted cell information generator 2120b of FIGS. 3 and 8.

In an embodiment, the inverted cell information generator 2212 may transfer the generated inverted cell information ICD to the memory controller 2100. The memory controller 2100 may determine whether a read reclaim operation is to be performed by counting a number of 1-value bits in the received inverted cell information ICD and comparing the counted number with a threshold value THR.

In another embodiment, the inverted cell information generator 2212 may additionally perform an operation of counting a number of 1-value bits in the generated inverted cell information ICD, and transfer that inverted bit number to the memory controller 2100. The memory controller 2100 may then determine whether the read reclaim operation is to be performed by comparing the received inverted bit number with the threshold value THR.

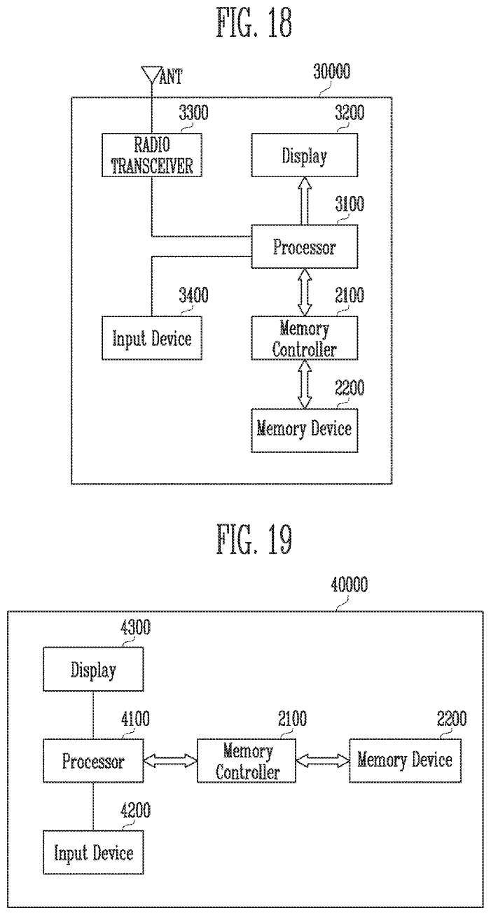

FIG. 18 is a diagram illustrating another example of the memory system including the memory controller shown in FIGS. 1 and 2.

Referring to FIG. 18, the memory system 30000 may be implemented as a cellular phone, a smart phone, a tablet PC, a personal digital assistant (PDA), or a wireless communication device. The memory system 30000 may include a memory device 2200 and a memory controller 2100 capable of controlling an operation of the memory device 2200.

The memory controller 2100 may control a data access operation of the memory device 2200, e.g., a program operation, an erase operation, a read operation, or the like under the control of a processor 3100.

Data programmed in the memory device 2200 may be output through a display 3200 under the control of the memory controller 2100.

A radio transceiver 3300 may transmit/receive radio signals through an antenna ANT. For example, the radio transceiver 3300 may convert a radio signal received through the antenna ANT into a signal that can be processed by the processor 3100. Therefore, the processor 3100 may process a signal output from the radio transceiver 3300 and transmit the processed signal to the memory controller 2100 or the display 3200. The memory controller 2100 may transmit the signal processed by the processor 3100 to the memory device 2200. Also, the radio transceiver 3300 may convert a signal output from the processor 3100 into a radio signal, and output the converted radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 2100, data output from the radio transceiver 3300, or data output from the input device 3400 can be output through the display 3200.

In some embodiments, the memory controller 2100 capable of controlling an operation of the memory device 2200 may be implemented as a part of the processor 3100, or be implemented as a chip separate from the processor 3100.

FIG. 19 is a diagram illustrating another example of the memory system including the memory controller shown in FIGS. 1 and 2.

Referring to FIG. 19, the memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include a memory device 2200 and a memory controller 2100 capable of controlling a data processing operation of the memory device 2200.

A processor 4100 may output data stored in the memory device 2200 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 2100. In some embodiments, the memory controller 2100 capable of controlling an operation of the memory device 2200 may be implemented as a part of the processor 4100, or be implemented as a chip separate from the processor 4100.

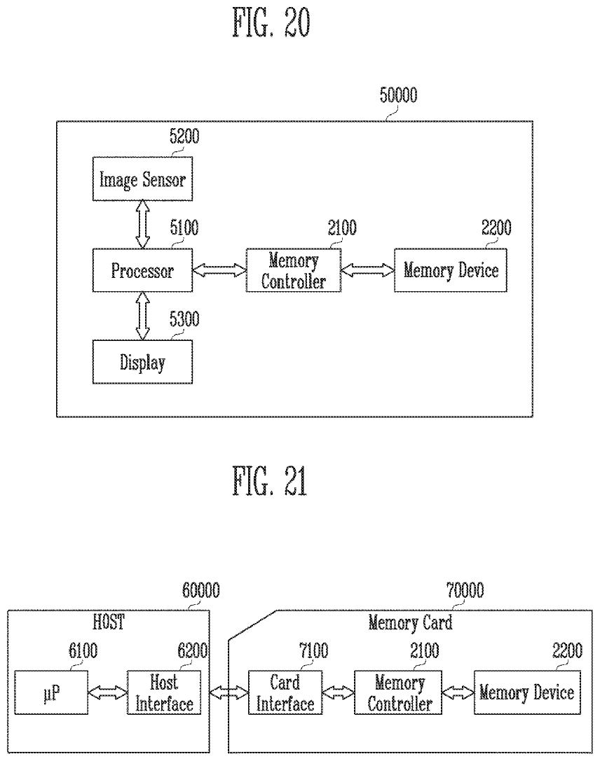

FIG. 20 is a diagram illustrating another example of the memory system including the memory controller shown in FIGS. 1 and 2.

Referring to FIG. 20, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 2200 and a memory controller 2100 capable of controlling a data processing operation of the memory device 2200, e.g., a program operation, an erase operation, or a read operation.

An image sensor 5200 of the memory system 50000 may convert an optical image into digital signals, and the converted digital signals may be transmitted to a processor 5100 or the memory controller 2100. Under the control of the processor 5100, the converted digital signals may be output through a display 5300, or be stored in the memory device 2200 through the memory controller 2100. In addition, data stored in the memory device 2200 may be output through the display 5300 under the control of the processor 5100 or the memory controller 2100.

In some embodiments, the memory controller 2100 capable of controlling an operation of the memory device 2200 may be implemented as a part of the processor 5100, or be implemented as a chip separate from the processor 5100.

FIG. 21 is a diagram illustrating another example of the memory system including the memory controller shown in FIGS. 1 and 2.

Referring to FIG. 21, the memory system 70000 may be implemented as a memory card or a smart card. The memory system 70000 may include a memory device 2200, a memory controller 2100, and a card interface 7100.

The memory controller 2100 may control data exchange between the memory device 2200 and the card interface 7100. In some embodiments, the card interface 7100 may be a Secure Digital (SD) card interface or a Multi-Media Card (MMC) interface, but the present disclosure is not limited thereto.

The card interface 7100 may interface data exchange between a host 60000 and the memory controller 2100 according to a protocol of the host 60000. In some embodiments, the card interface 7100 may support a Universal Serial Bus (USB) protocol and an Inter-Chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 2200 through the card interface 7100 and the memory controller 2100 under the control of a microprocessor (μP) 6100.

In accordance with embodiments of the present disclosure, a memory system for efficiently performing read reclaim, a memory controller, and an operating method thereof is provided.

Various embodiments have been disclosed herein, and although specific terms are employed, they are used and are to be interpreted in a generic and descriptive sense and not for purpose of limitation. In some instances, as would be apparent to one skilled in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory system comprising:
a memory device including a plurality of memory cells; and
a memory controller configured to control the memory device to perform a plurality of read operations on memory cells in a selected physical page among the plurality of memory cells, calculate an inverted bit number representing different bit values, based on a plurality of read data received from the memory device, and perform a read reclaim operation on the selected physical page, based on the inverted bit number.

2. The memory system of claim 1, wherein the memory controller includes:
a command generator configured to generate first and second read commands for reading data of the selected physical page;
an inverted cell information generator configured to generate inverted cell information based on first and second read data respectively corresponding to the first and second read commands; and
a read reclaim controller configured to determine whether the read reclaim operation on the selected physical page is to be performed based on the inverted cell information.

3. The memory system of claim 2, wherein the inverted cell information generator includes:
a first read data storage configured to store the first read data;
a second read data storage configured to store the second read data; and
an exclusive OR (XOR) operator configured to generate the inverted cell information by performing an XOR operation on the first read data and the second read data.

4. The memory system of claim 2, wherein the read reclaim controller includes:
an inverted bit counter configured to calculate the inverted bit number by counting a number of inverted bits in the inverted cell information;
a threshold value storage configured to store a threshold value;
a comparator configured to compare the inverted bit number with the threshold value; and
a read reclaim determiner configured to determine whether the read reclaim operation on the physical page is to be performed based on the comparison result of the comparator.

5. The memory system of claim 4, wherein, when the inverted bit number is greater than or equal to the threshold value as the comparison result of the comparator, the read reclaim determiner determines that the read reclaim operation on the physical page is to be performed.

6. The memory system of claim 5, wherein, when the read reclaim determiner determines that the read reclaim operation on the physical page is to be performed, the memory controller stores data stored in the selected physical page in another physical page.

7. The memory system of claim 6,
further comprising an internal memory configured to store an address mapping table including a mapping relationship between logical and physical addresses,
wherein, when the read reclaim determiner determines that the read reclaim operation on the physical page is to be performed, the memory controller updates the address mapping table stored in the internal memory.

8. The memory system of claim 2, wherein the memory controller performs error correction on at least one of the first read data and the second read data and transfers the error-corrected data to a host.

9. A memory controller for controlling a memory device under the control of a host, the memory controller comprising:
a command generator configured to generate first and second read commands for controlling the memory device to repeatedly perform a read operation on a physical page in response to a read request from the host;
an inverted cell information generator configured to generate inverted cell information based on first and second read data received from the memory device respectively corresponding to the first and second read commands; and
a read reclaim controller configured to generate a control signal for performing a read reclaim operation on the physical page based on an inverted bit number included in the inverted cell information.

10. The memory controller of claim 9, wherein the inverted cell information generator includes:
a first read data storage configured to store the first read data;
a second read data storage configured to store the second read data; and
an XOR operator configured to generate the inverted cell information by performing an XOR operation on the first read data and the second read data.

11. The memory controller of claim 9, wherein the read reclaim controller includes:
an inverted bit counter configured to calculate the inverted bit number by counting a number of inverted bits in the inverted cell information;
a threshold value storage configured to store a threshold value;
a comparator configured to compare the inverted bit number with the threshold value; and
a read reclaim determiner configured to determine whether the read reclaim operation on the physical page is to be performed based on the comparison result of the comparator.

12. The memory controller of claim 11, wherein, when the inverted bit number is greater than or equal to the threshold value, the read reclaim determiner generates a control signal to control the memory device to perform the read reclaim operation on the physical page.

13. The memory controller of claim 12,
further comprising an internal memory configured to store an address mapping table,
wherein the address mapping table stored in the internal memory is updated in response to the control signal.

14. A method for operating a memory controller, the method comprising:
issuing a read command for repeatedly reading a selected page of a memory device, and receiving read data from the memory device;
generating inverted cell information based on the read data; and
determining whether a read reclaim operation on the selected page is to be performed based on the inverted cell information.

15. The method of claim 14, wherein the issuing of the read command to the memory device and the receiving of the read data from the memory device include:
issuing a first read command for reading the selected page;
receiving first read data corresponding to the first read command from the memory device;
issuing a second read command for re-reading the selected page; and
receiving second read data corresponding to the second read command.

16. The method of claim 15, wherein the generating of the inverted cell information based on the read data includes generating the inverted cell information by performing an XOR operation on the first read data and the second read data.

17. The method of claim 16, wherein the determining of whether the read reclaim operation on the selected page is to be performed includes:
counting a number of bits of a first value, among two values, in the inverted cell information to generate a counted result;
comparing the counted result with a threshold; and
determining whether the read reclaim operation on the selected page is to be performed based on the comparison result.

18. The method of claim 17, wherein the determining of whether the read reclaim operation on the selected page is to be performed includes determining that the read reclaim operation on the selected page is to be performed when the counted result is greater than or equal to the threshold.
